(19) United States
(12) Patent Application Publication
(10) Pub. No.: US 2010/0078619 A1
(43) Pub. Date: Apr. 1, 2010

(54) RESISTIVE MEMORY CELL AND METHOD FOR MANUFACTURING A RESISTIVE MEMORY CELL

(75) Inventors: Andrea Redaelli, Lecco (IT); Fabio Pellizzer, Cornate D'Adda (IT); Agostino Pirovano, Corbetta (IT)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS S.R.L., Agrate Brianza (IT)

(21) Appl. No.: 12/570,256

(22) Filed: Sep. 30, 2009

(30) Foreign Application Priority Data
Sep. 30, 2008 (IT) TO2008A 000715

(51) Int. Cl. H01L 45/00; H01L 21/02

(52) U.S. Cl. 257/3; 438/382; 257/E45.002; 257/E21.006; 438/102

(57) ABSTRACT

A resistive memory cell includes a structural layer, a pore in the structural layer, a selector, having a coupling terminal accommodated in the pore, and a storage element of a resistive memory material, arranged in the pore and electrically coupled to the coupling terminal of the selector. The storage element has a tubular portion, extending transversely to an electrical coupling interface of the coupling terminal.

### BACKGROUND

1. Technical Field

The present disclosure relates to a resistive memory cell and to a method for manufacturing a resistive memory cell.

2. Description of the Related Art

As is known, resistive memories are based on storage materials that may switch between different states and show different resistivities, depending on the selected state.

In particular, phase change memories use a class of materials that have the property of switching between two phases having distinct electrical characteristics, associated with two different crystallographic structures of the material: an amorphous, disorderly phase, and a crystalline or polycrystalline, orderly phase. The two phases are hence associated to resistivities of considerably different values.

Currently, the alloys of elements of group VI of the periodic table, such as Te or Se, referred to as chalcogenides or chalcogenic materials, can be used advantageously in phase change memory cells. The currently most promising chalcogenide is formed from an alloy of Ge, Sb and Te (Ge₂Sb₂Te₅), also called GST, which is now widely used for storing information on overwritable disks and has been also proposed for mass storage.

In chalcogenides, the resistivity varies by two or more orders of magnitude when the material passes from the amorphous (more resistive) phase to the crystalline (more conductive) phase, and vice versa.

Phase change can be obtained by locally increasing the temperature. Below 150° C., both phases are stable. Starting from an amorphous state, and raising the temperature above 200° C., there is a rapid nucleation of the crystallites and, if the material is kept at the crystallization temperature for a sufficiently long time, it undergoes a phase change and becomes crystalline. To bring the chalcogenide back to the amorphous state it is necessary to raise the temperature above the melting temperature (approximately 600° C.) and then rapidly cool down the chalcogenide.

From an electrical point of view, the crystallization temperature and the melting temperature may be obtained by causing an electric current to flow through the resistive electrode in contact or close proximity with the chalcogenic material and thus heating the chalcogenic material by Joule effect.

In particular, when the chalcogenic material is in the amorphous, high resistivity state (also called the reset state), it is necessary to apply current pulses of suitable length and amplitude and allow the chalcogenic material to cool slowly and crystallize. In this condition, the chalcogenic material changes its state and switches from a high resistivity to a low resistivity state (also called the set state).

Vice versa, when the chalcogenic material is in the set state, it is necessary to apply a current pulse of suitable length and high amplitude so as to cause the chalcogenic material to switch to the amorphous phase.

Memory devices exploiting the properties of chalcogenic material (also called phase change memory devices) have been already proposed.

The composition of chalcogenides suitable for the use in a phase change memory device and a possible structure of a phase change element is disclosed in a number of documents (see, e.g., U.S. Pat. No. 5,825,046).

As discussed in EP-A-1 326 254 (corresponding to US-A-2003/0185047) a memory element of a phase change memory device comprises a chalcogenic material and a resistive electrode, also called heater. The heater may be in the form of a thin wall or a rod and a layer of phase-change material is deposited on the heater. The memory element is formed at a contact area of the heater and the phase-change material, which is made as small as possible.

In a different kind of known phase-change memories, also called “pore” memories, a memory cell comprise a diode, formed in a hole or pore and functioning as a selector, and a memory element formed on the diode. In practice, each pore accommodates a stack of three generally planar layers: first and second semiconductor layers, having opposite conductivities and forming the diode, and a phase-change material in contact with the diode.

However, neither memories including heaters, nor pore memories are likely to meet the scaling requirements that are becoming more and more important in any application of microelectronics. In fact, although the provision of heaters and small area contacts (few square nanometers) allow using very low programming currents, heaters make manufacture of memory devices quite complex and expensive and inherently hinder shrinking device dimensions. On the contrary, pore memories are compact, but involve high currents to program memory elements because of large cross section of current paths through phase-change material. Basically, the cross section is the same as that of the pore and therefore resistance of the memory element is very low. In order to provide sufficient heating to cause phase transition, high programming currents must be delivered, contrary to the requirement to reduce power consumption and write throughput.

### BRIEF SUMMARY

Embodiments include a resistive cell and a method for manufacturing a resistive cell, which are free from the above-described limitations.

One embodiment is a resistive memory cell that includes a structural layer, a pore in the structural layer, a selector having a coupling terminal positioned in the pore, and a storage element of a resistive memory material. The storage element is arranged in the pore and includes a tubular portion extending transversely to an electrical coupling interface of the coupling terminal.

### BRIEF DESCRIPTION OF THE SEVERAL VIEWS OF THE DRAWINGS

For the understanding of the present disclosure, some embodiments thereof will be now described, purely as non-limitative examples, with reference to the enclosed drawings, wherein:

FIG. 1 is a simplified circuit diagram of a phase change memory device according to one embodiment;

FIG. 2a is a cross-sectional view through the phase change memory device of FIG. 1;

FIG. 2b shows a detail of a phase change memory device according to another embodiment;

FIG. 2c shows a detail of a phase change memory device according to another embodiment;

FIG. 2d shows a detail of a phase change memory device according to another embodiment;

FIG. 3 is a sectional top plan view of an enlarged detail of the memory device of FIG. 1, taken along the line III-III of FIG. 2a;

FIG. 4 is a cross-sectional view through a semiconductor wafer in an initial step of a manufacturing process according to one embodiment;

FIG. 5 is a cross sectional view through the wafer of FIG. 4, taken along the line V-V of FIG. 4;

FIGS. 6-10 show the same view as FIG. 4, in subsequent manufacturing steps;

FIG. 11 is a simplified circuit diagram of a phase change memory device according to another embodiment;

FIG. 12 is a cross-sectional view through the phase change memory device of FIG. 11;

FIG. 13 is a cross-sectional view through a semiconductor wafer in an initial step of a manufacturing process according to another embodiment;

FIG. 14 is a cross sectional view through the wafer of FIG. 13, taken along the line XIV-XIV of FIG. 13, in a subsequent manufacturing step;

FIGS. 15-17 show the same view as FIG. 13, in subsequent manufacturing steps;

FIG. 18 is a simplified circuit diagram of a phase change memory device according to another embodiment;

FIG. 19 is a cross-sectional view through the phase change memory device of FIG. 18;

FIGS. 20-23 are cross-sectional views through a semiconductor wafer in subsequent steps of a manufacturing process according to another embodiment; and

FIG. 24 is a system depiction of one embodiment.

### DETAILED DESCRIPTION

In the following description of some embodiments of the present disclosure, reference will be made to phase-change memories, based on chalcogenides as storage materials. However, it is understood that the scope of the disclosure is not limited thereto and includes any kind of resistive memory cells and resistive memories, based on materials which may be switched between states having different resistivities by applying appropriate currents or voltages. Such materials, which will be hereinafter referred to as resistive memory materials, include e.g., binary oxides and organic films, among others.

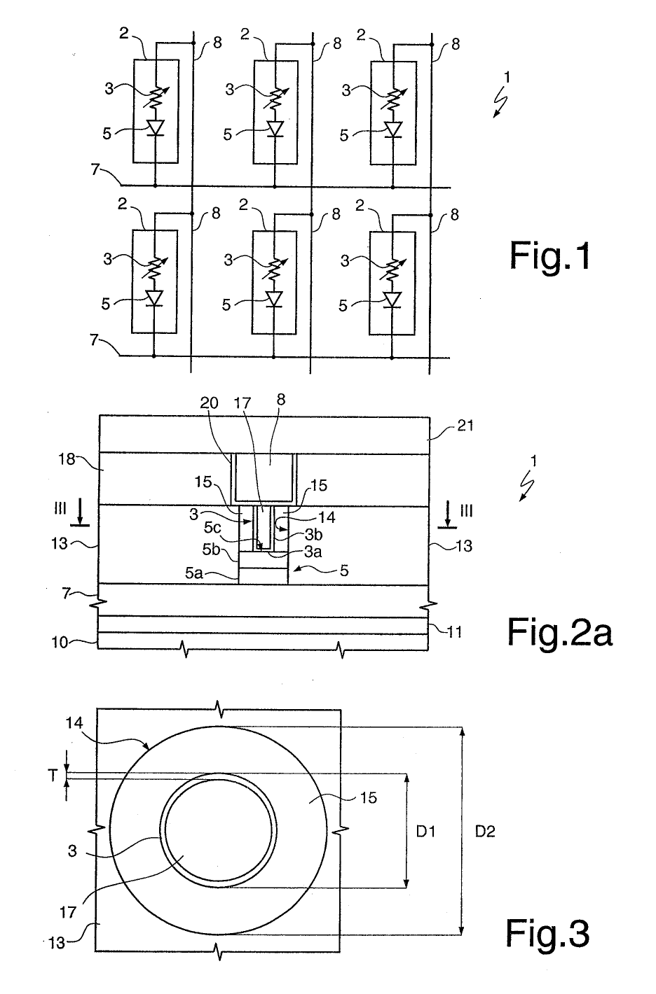

In FIG. 1, a resistive memory device, namely a phase-change memory device, is indicated by the reference number 1 and comprises plurality of resistive phase-change memory cells or PCM cells 2, arranged in rows and columns to form an array. The array includes a plurality of word lines 7 and a plurality of bit lines 8. PCM cells 2 arranged on the same row are coupled to a respective word line 7 and PCM cells 2 arranged on the same column are coupled to a same bit line 8.

Each PCM cell 2 includes a storage element 3, of a resistive memory material, in particular a phase-change material, and a selector 5, for selectively connecting the storage element 3 with the respective word line 7. In one embodiment, the phase-change material is a chalcogenide, such as GST, but any other material may be used, that is electrically switchable between different states, each having associated a respective resistance level. In the embodiment of FIG. 1, moreover, the selector 5 includes a semiconductor diode having its anode connected to a first terminal of the storage element 3 and its cathode connected to the respective word line 7. A second terminal of the storage element 3 is connected to the respective bit line 8. In one embodiment, not illustrated, the polarity of the diode may be inverted.

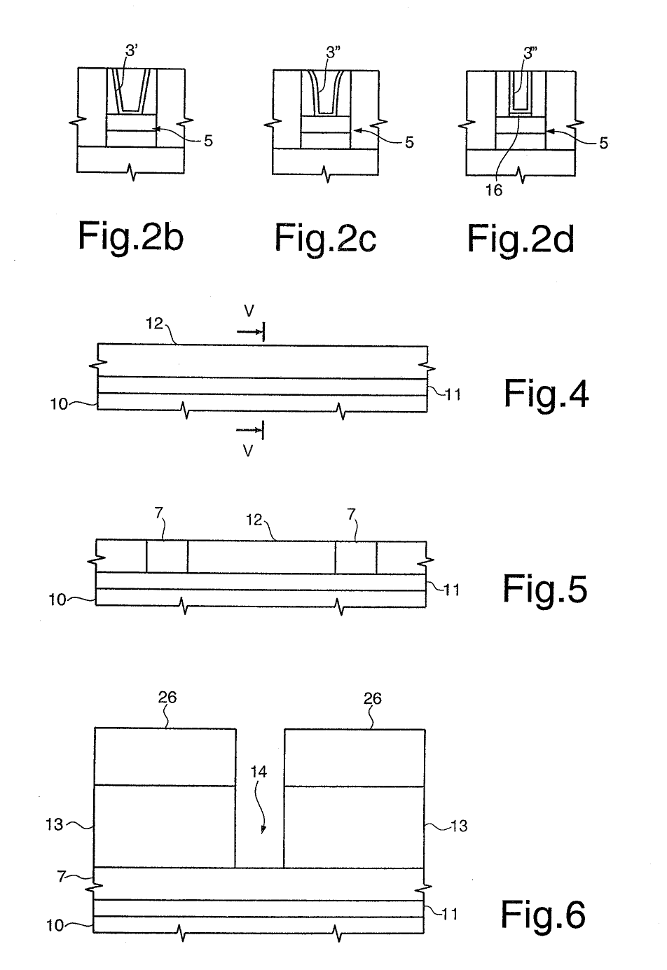

As shown in FIGS. 2a and 3, the phase-change memory device 1 is formed in a SOI semiconductor wafer that comprises a monocrystalline P-type substrate 10 and an insulating layer 11. Word lines 7 are formed from a N-type monocrystalline region of the SOI wafer and run in a first direction, parallel to a surface of the substrate 10. Adjacent word lines 7 are separated by a dielectric material 12, e.g., silicon dioxide (see FIG. 5 for this detail). A pore structural layer 13 of dielectric material, e.g., silicon dioxide, is arranged on the word lines 7 and circular pores 14 are formed therein, perpendicularly to the word lines 7 and to the surface of the substrate 10. In other embodiments, pores may have different shape, such as elliptical or generally squared or rectangular, possibly with rounded corners.

Each pore 14 accommodates one storage element 3 and one selector 5.

The selector 5 comprises a first junction region 5a, of N⁺-type, and a second junction region 5b, of P⁺-type, which are arranged to form a PN junction and define the cathode and the anode of the selector 5, respectively. The first junction region 5a is in contact with the word line 7 at the bottom of the pore 14 and the second junction region 5b is stacked on the first junction region 5a. Both the first junction region 5a and the second junction region 5b extend as far as the cross section of the pore 14 or, in other words, they are aligned therewith. A surface of the second junction region 5b, that is opposite to the first junction region 5a and parallel to the surface of the substrate 10, defines a coupling interface 5c of the selector 5, for electrical coupling with the storage element 3.

The storage element 3 is formed directly in contact with the second junction region 5b, in the embodiment herein described, and is separated from the wall of the pore 14 by an annular spacer 15. Hence, a first cross dimension (external diameter D1, in the embodiment herein described) of the storage element 3 is smaller than a corresponding second cross dimension (pore diameter D2) or the pore 14 (see FIG. 3). First and second cross dimensions are herein considered along a direction that is parallel to the coupling interface 5c of the selector 5. The storage element 3 is in the form of an elongated, cup-shaped body, with a bottom portion 3a that adheres to the second junction region 5b and a hollow tubular portion 3b which extends in a second direction, transverse (perpendicular in the present embodiment) to the first direction (i.e., to the word line 7) and to the coupling interface 5c of the selector 5. The tubular portion 3b is embedded within the spacer 15 and is conformal to an internal surface thereof. In one embodiment, in particular, the tubular portion 3b of the storage element 3 is cylindrical, as shown in FIGS. 2a and 3, and is defined by a wall having a thickness T of between 5 nm and 20 nm. However, in other embodiments also different shapes and dimensions may be envisaged. For example, the tubular portion 3b may be in the form of a truncated cone (see 3′ in FIG. 2b), possibly with rounded walls (3″ as illustrated in the embodiment of FIG. 2c). In one embodiment, moreover, a barrier layer 16, e.g., of TiN, is formed between the selector 5 and the storage element 3′″, as shown in FIG. 2d.

The interior of the storage element 3 is filled with a dielectric core 17, that is made of silicon nitride in the embodiment herein described.

The bit lines 8 are accommodated in a bit line structural layer 18, that is made of dielectric material, e.g., silicon dioxide, and is formed on the pore structural layer 13. The bit lines 8 run in a third direction or column direction, that is parallel to the surface of the substrate 10 and perpendicular to the row direction (i.e., to the word lines 7). Conductive barriers 20 coat the bit lines 8 and are directly in contact with the tubular portions 3b of the storage elements 3. Thus, the bit lines 8 are coupled with the storage elements 3 of PCM cells 2 arranged on a same column.

A protective layer 21, e.g., of silicon dioxide, covers the entire phase-change memory device 1. Word line contacts and bit line contacts are provided in a manner in itself known and are not illustrated for the sake of simplicity.

The tubular portion 3b of the storage element 3 has very high resistance, because of its thickness in the order of few nanometers. Thus, small programming currents may produce significant heating and cause phase transition of at least part of the tubular portion 3b of the storage element 3 even in the absence of a dedicated heater. For example, programming currents of about 200 μA may be used for a storage element having a thickness T of 5 nm and an external diameter D1 of 30 nm. In particular, phase transition first takes place at an intermediate section of the tubular portion 3b, because temperature increments are lower at interfaces with the word line 7 and the bit line 8 (or the barrier 20). The word line 7 and the bit line 8, in fact, have high thermal conductivity. However, complete phase transition of the whole storage element 3 is not required, because change of state of a small section from crystalline to amorphous is sufficient to produce substantial increment of the overall resistance.

A process for manufacturing the phase-change memory 1 will be now described with reference to FIGS. 4 to 10.

Initially, a SOI semiconductor wafer 25, that includes the P-type substrate 10, the insulating layer 11 and a N-type monocrystalline region thereon, is defined by a masked etch to form the word lines 7 from the monocrystalline region. Then, the dielectric material 12 is deposited and the wafer is planarized, thereby obtaining the structure illustrated in FIGS. 4 and 5.

The pore structural layer 13 is deposited on the word lines 7 and the dielectric material 12, as illustrated in FIG. 6, and a pore mask 26 is formed, which has apertures above regions where pores 14 are to be made. The pore structural layer 13 is then anisotropically etched through the pore mask 26 to open pores 14, that in the embodiment herein described are circular.

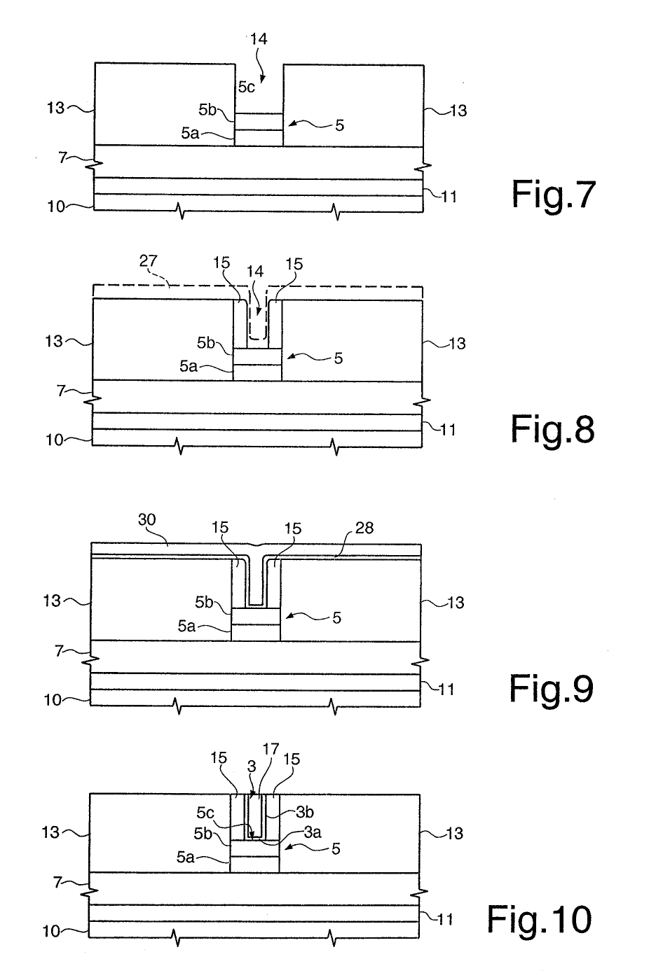

A two-step epitaxial growth is then carried out to form selectors 5 in the pores 14, as shown in FIG. 7. In a first step, N-type dopants are provided to form the first junction region 5a (N⁺), whereas in the second step the second junction region 5b (P⁺) is made by addition of P-type dopants.

A spacer layer 27 (indicated by a dashed line in FIG. 8) is deposited on the pore structural layer 13 and in the pores 14, which are only partially filled. The spacer layer 27 is then etched back to form the spacers 15. More precisely, the spacer layer 27 is removed completely from above the pore structural layer 13 and in part from the bottom of the pores 14. Thus, the second junction region 5b of the selectors 5 is exposed at center thereof, while the walls of the pore 14 are coated by spacers 15. The cross-dimension (diameter, in the embodiment herein described) of the pores 14 is therefore reduced by about twice the thickness of the spacer layer 27.

As illustrated in FIG. 9, a phase-change layer 28 is then conformally deposited on the wafer 25 until it reaches a controlled thickness (of e.g., 5 nm to 20 nm). Conformality is achieved by a CVD (Chemical Vapor Deposition) process, in particular MOCVD (Metal Organic CVD) in one embodiment. The thickness of the phase-change layer 28 is much lower than the cross dimension of the pores 14, even after diameter shrank because of formation of spacers 15. Thus, the interior of the pores 14 remains hollow. Next, a filler layer 30 of dielectric material, e.g., silicon nitride, is deposited on the wafer 25 and fills the pores 14.

The wafer 25 is then planarized by a CMP process that is arrested on the pore structural layer 13, as shown in FIG. 10. In this stage, the filler layer 30 and the phase change layer 28 are removed from above the pore structural layer 13. Phase-change material is confined in the pores 14 and forms storage elements 3. Residual portions of the filler layer 30 form cores 17 within tubular portions 3b of the storage elements 3.

Then, the bit line structural layer 18 is deposited on the wafer 25, the bit lines 8 are formed therein by a Cu-damascene technique and the protective layer 21 is finally formed, thus obtaining the structure of FIG. 1. In particular, the bit line structural layer 18 is selectively etched to define bit line trenches above the pores 14, a barrier layer and a conductive layer (e.g., Cu) are sequentially deposited, and the structure is planarized by a second CMP process, so that residual portions of the barrier layer and a conductive layer form the barriers 20 and the bit lines 8 in the bit line trenches. Once the bit lines 8 are terminated, the protective layer 21 is deposited and the wafer 25 is cut into dice, thereby obtaining the memory device 1 of FIG. 2.

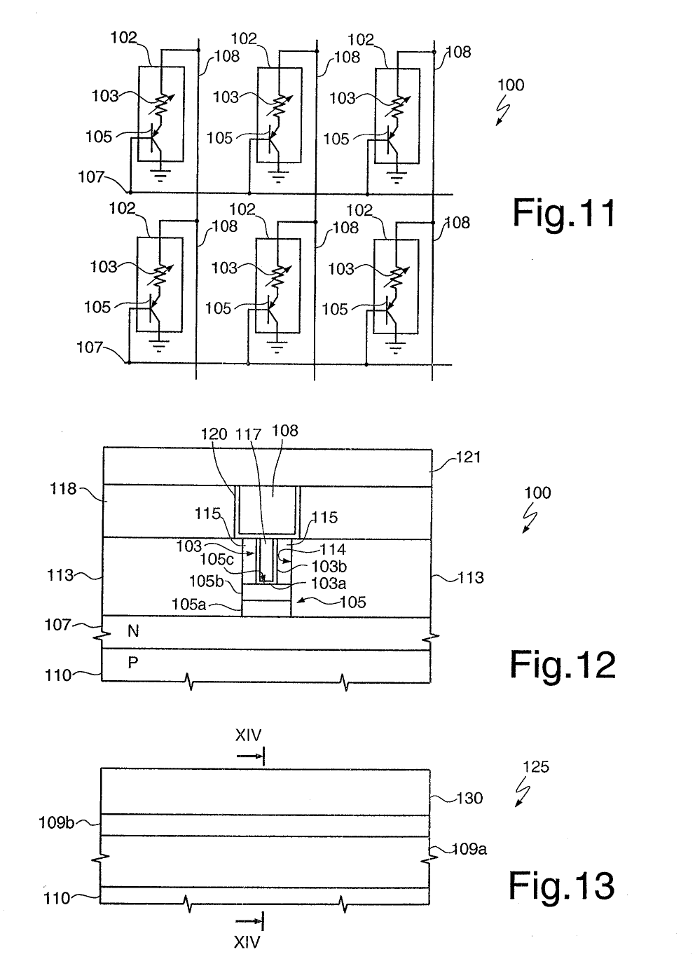

According to another embodiment, illustrated in FIGS. 11 and 12, a phase-change memory 100 comprises a plurality of phase-change memory cells or PCM cells 102, arranged in rows and columns to form an array. PCM cells 102 arranged on the same row are coupled to a respective word line 107 and PCM cells 102 arranged on the same column are coupled to a same bit line 108.

Each PCM cell 102 includes a storage element 103, of a phase change material, and a selector 105, for selectively connecting the storage element 103 with the respective word line 107. Selectors 105 include bipolar transistors, in particular PNP transistors in the embodiment herein described.

As shown in FIG. 12, pores 114 are formed in a pore structural layer 113, that is arranged on the word lines 107. Each pore 114 accommodates one storage element 103 and in part one selector 105.

Each selector 105 comprises a PNP bipolar transistor having a common collector, that includes a P-type substrate 110, a common base, that includes a respective N-type word line 107 and extends according to a first direction, a raised base region 105a, also of N-type, and an emitter terminal 105b, of P-type, stacked on the raised base region 105a. The raised base region 105a and the emitter terminal 105b form a PN junction, are accommodated within the respective pore 114 and have the same cross dimension (diameter). A surface of the emitter terminal 105b, that is opposite to the raised base region 105a and parallel to the surface of the substrate 110, defines a coupling interface 105c of the selector 105, for electrical coupling with the storage element 103.

The storage element 103 is identical to the storage element 3 of FIGS. 2 and 3 and includes an elongated, cup-shaped body, with a bottom portion 103a and a hollow tubular portion 103b, which extend in a second direction, perpendicular to the first direction (i.e., to the word line 107) and to the coupling interface 105c. The tubular portion 103b has smaller cross dimension than the pore 114 and is separated from the wall of the pore 114 by spacers 115. More precisely, the tubular portion 103b is embedded within the spacer 115 and is conformal to an internal surface thereof. The interior of the storage element 103 is filled with a dielectric core 117.

Bit lines 108 are accommodated in a bit line structural layer 118, that is made of dielectric material, e.g., silicon dioxide, and is formed on the pore structural layer 113. The bit lines 108 run in a third direction, that is parallel to the surface of the substrate 110 and perpendicular to the first direction (i.e., to the word lines 107). Conductive barriers 120 coat the bit lines 108 and are directly in contact with the tubular portions 103b of the storage elements 103. Thus, the bit lines 108 are coupled with the storage elements 103 of PCM cells 102 arranged on a same column. The memory device 100 is covered by a protective layer 121.

The memory device 100 may be made substantially as described with reference to FIGS. 4-10, except in that formation of word lines 107 includes growing an epitaxial layer from the substrate 110 and defining the epitaxial layer by masked etch that is terminated on reaching the substrate 110 (instead of starting from a SOI wafer that is etched on one side).

According to another embodiment, the memory device 100 may be made as hereinafter described, with reference to FIGS. 13-17.

In the substrate 110 of a semiconductor wafer 125, of P-type, a first and a second ion implantation are initially carried out to form a first conduction layer 109a and a second conduction layer 109b, having opposite conductivities. In particular, the first conduction layer 109a is of N-type and the second conduction layer 109b is of P-type. A dielectric layer 130, e.g., of silicon nitride, is formed on the second conduction layer 109b.

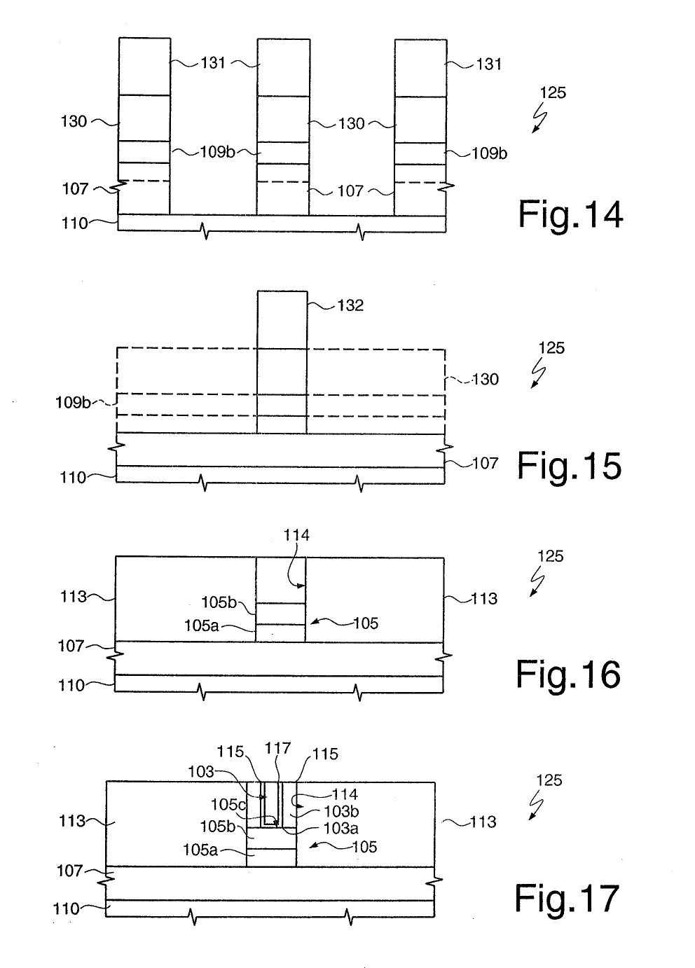

The dielectric layer 130, the first conduction layer 109a and the second conduction layer 109b are sequentially defined by first a self-aligned etch through a word line mask 131, to form word lines 107, as shown in FIG. 14. The etch is arrested soon after reaching the substrate 110, so as to cause some over-etch.

A second self-aligned etch is then carried out through a selector mask 132 (FIG. 15), to define the dielectric layer 130 and form the raised base region 105a and the emitter terminal 105b from the second conduction layer 109b and the first conduction layer 109a, respectively. During the second self-aligned etch, which is time-controlled, the word lines 107 are thinned out and reduced to their final thickness.

After removing the selector mask 132, the pore structural layer 113 is deposited and the wafer 125 is planarized by CMP until remainder portions of the dielectric layer 130 are exposed, thereby obtaining the structure illustrated in FIG. 16. In particular, following upon deposition and planarization, pores 114 are formed and accommodate raised base regions 105a and emitter terminals 105b of respective selectors 105, besides a portion of dielectric material from the dielectric layer 130.

Then, the remainder of the dielectric layer 130 is etched back and removed from inside the pores 114 (FIG. 17). As already described with reference to FIG. 8-10, spacers 115 and storage elements 103 are formed in the pores 114 (deposition and etch back of a spacer layer, conformal deposition of chalcogenic material, deposition of a filler layer and further CMP planarization).

Finally, the bit line structural layer 118, the bit lines 108 and the protective layer 121 are formed and the wafer 125 is divided into dice, thus arriving at the memory device 100 illustrated in FIG. 11.

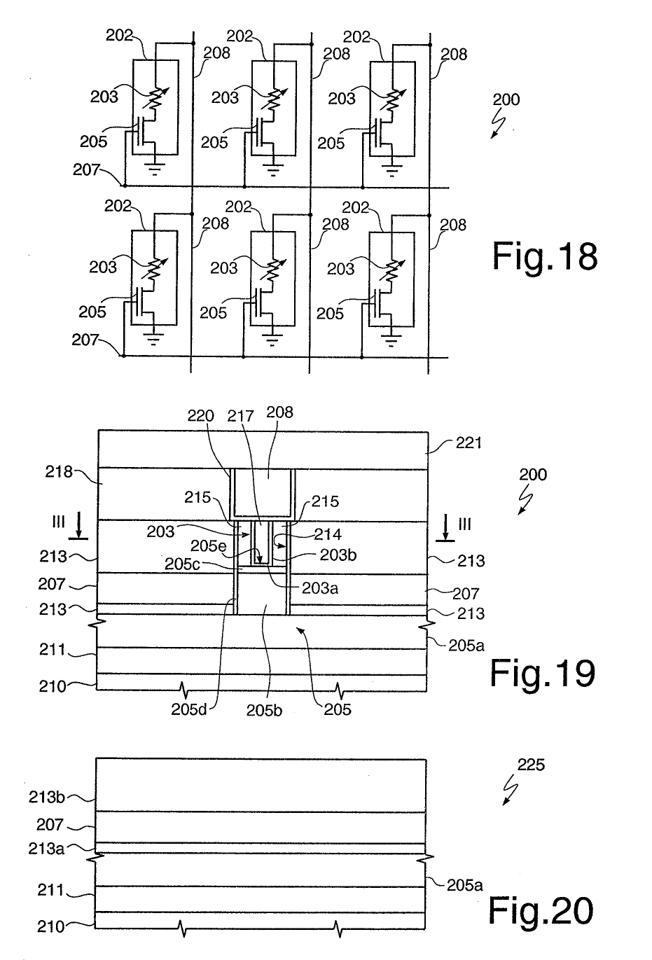

Another embodiment of the invention is illustrated in FIGS. 18 and 19. A phase-change memory 200 comprises a plurality of phase-change memory cells or PCM cells 202, arranged in rows and columns to form an array. PCM cells 202 arranged on the same row are coupled to a respective word line 207 and PCM cells 202 arranged on the same column are coupled to a same bit line 208.

Each PCM cell 202 includes a storage element 203, of a phase change material, and a selector 205, for selectively connecting the storage element 203 with the respective word line 207. Selectors 205 include NMOS transistors in the embodiment herein described.

As shown in FIG. 19, the phase-change memory device 200 is formed in a SOI semiconductor wafer that comprises a monocrystalline P-type substrate 210 and an insulating layer 211. A continuous common source region 205a of selectors 205 is formed from a N-type monocrystalline region of the SOI wafer and is arranged on the insulating layer 211. A pore structural layer 213, in which pores 214 are formed, covers the insulating layer 211. The pore structural layer 213 also accommodates polysilicon word lines 207, which extend at a distance from the common source region 205a and according to a first direction, that is parallel to the surface of the substrate 210. Word lines 207 connect pores 214, which are aligned according to the first direction. Pores 214 extend along a second direction, perpendicular to the first direction and to the surface of the substrate 210, and are surrounded by the respective word lines 207. Moreover, each pore 214 is internally coated by gate oxide regions 205d and includes a storage element 203 and part of a respective selector 205, namely a channel region 205b and a drain terminal 205c.

The drain terminal 205c, of N-type, is stacked on the channel region 205b, of P-type, and both have the same cross dimension as the pore 214. A surface of the drain terminal 205c, that is opposite to the channel region 205b and parallel to the surface of the substrate 210, defines a coupling interface 205e of the selector 205, for electrical coupling with the storage element 203.

The storage element 203 is identical to the storage element 3 of FIGS. 2 and 3 and includes an elongated, cup-shaped body, with a bottom portion 203a and a hollow tubular portion 203b, which extend along the second direction (i.e., perpendicular to the word line 207 and the surface of the substrate 210). The tubular portion 203b has smaller cross dimension than the pore 214 and is separated from the wall of the pore 214 by a spacer 215. More precisely, the tubular portion 203b is embedded within the spacer 215 and is conformal to an internal surface thereof. The interior of the storage element 203 is filled with a dielectric core 217.

Bit lines 208 are accommodated in a bit line structural layer 218, that is made of dielectric material, e.g., silicon dioxide, and is formed on the pore structural layer 213. The bit lines 208 run in a third direction, that is parallel to the surface of the substrate 210 and perpendicular to the first direction (i.e., to the word lines 207). Conductive barriers 220 coat the bit lines 208 and are directly in contact with the tubular portions 203b of the storage elements 203. Thus, the bit lines 208 are coupled with the storage elements 203 of PCM cells 202 arranged on a same column.

Manufacturing of the memory device 200 will be hereinafter described, with reference to FIGS. 20-23.

In a SOI semiconductor wafer 225, having a P-type substrate 210, an insulating layer 211 and a monocrystalline N-type region, the monocrystalline N-type region defines the N-type common source region 205a for selectors 205 that will be made. The N-type common source region 205a is covered by a first structural layer 213a of dielectric material. A polysilicon layer is deposited on the first structural layer 213a and defined to from word lines 207. A second structural layer 213b, of the same dielectric material as the first structural layer 213a, is then deposited and joins the first structural layer 213a, thereby forming the pore structural layer 213 in which the word lines 207 are embedded. The structure of FIG. 20 is thus obtained.

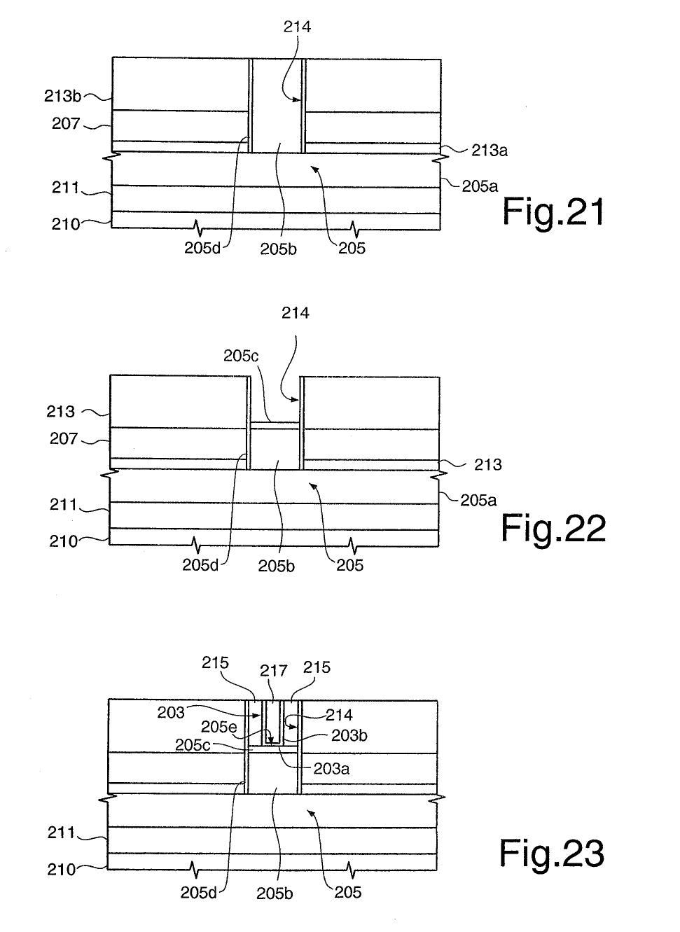

As illustrated in FIG. 21, pores 214 are opened in the pore structural layer 213 through the word lines 207, until the common source region 205a is exposed. Then, the walls of the pores 214 are coated with silicon dioxide to form the gate oxide regions 205b and the pores 214 are filled with P-type silicon (indicated by 230 in FIG. 21). The wafer 225 is then planarized.

The P-type silicon 230 is then etched until its thickness approaches the level of the upper surface of the word lines 207, as shown in FIG. 22. N-type ion implantation is carried out to form the drain terminals 205c in the portion of the P-type silicon that exceeds the word lines 207. The remainder portion of the P-type silicon defines the channel region 205b.

Then, the spacers 215 and the storage elements 203 are formed in free portions of the pores 214, as already described with reference to FIG. 8-10.

The manufacturing process is terminated by forming the bit line structural layer 218, the bit lines 208 and the protective layer 221, and by dividing the wafer 225 into dice, to obtain the phase change memory of FIG. 19.

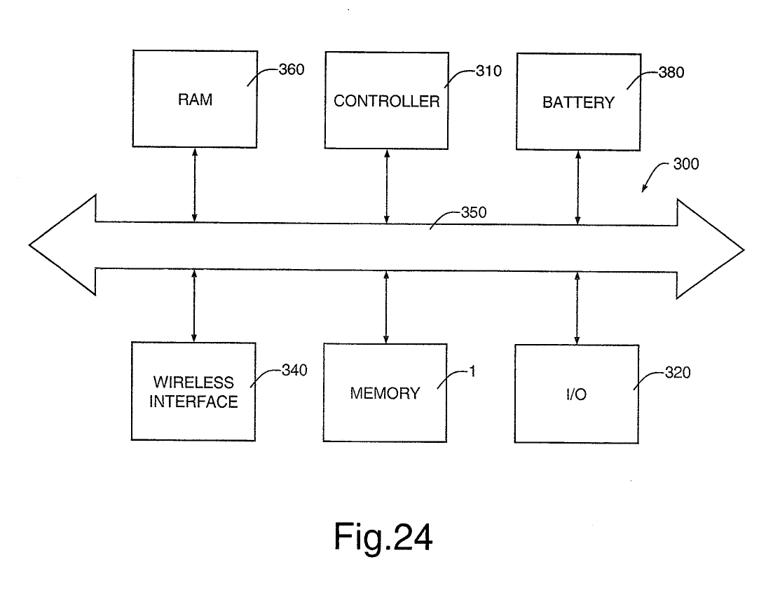

In FIG. 24, a portion of a system 300 in accordance with an embodiment of the present disclosure is illustrated. System 300 may be used in devices such as, for example, a personal digital assistant (PDA), a laptop or portable computer, possibly with wireless capability, a cell phone, a messaging device, a digital music player, a digital camera, or other devices that may be adapted to process, store, transmit or receive information and employ permanent storage capability.

System 300 may include a controller 310, an input/output (I/O) device 320 (e.g., a keyboard, display), the phase-change memory 1, a wireless interface 340, and a RAM memory 360, coupled to each other via a bus 350. A battery 380 may be used to supply power to the system 300 in one embodiment. It should be noted that the scope of the present invention is not limited to embodiments having necessarily any or all of above listed components.

Controller 310 may comprise, for example, one or more microprocessors, digital signal processors, micro-controllers, or the like.

The I/O device 320 may be used to generate a message. The system 300 may use the wireless interface 340 to transmit and receive messages to and from a wireless communication network with a radio frequency (RF) signal. Examples of the wireless interface 340 may include an antenna, or a wireless transceiver, such as a dipole antenna, although the scope of the present invention is not limited in this respect. Also, the I/O device 320 may deliver a voltage reflecting what is stored as either a digital output (if digital information was stored), or as analog information (if analog information was stored).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A resistive memory cell comprising:
a structural layer;
a pore in the structural layer;
a selector having a coupling terminal positioned in the pore, the coupling terminal including an electrical coupling interface;
a storage element of a resistive memory material, the storage element being arranged in the pore, being electrically coupled to the coupling terminal of the selector, and including a tubular portion extending transversely to the electrical coupling interface of the coupling terminal.

2. A resistive memory cell according to claim 1, wherein the tubular portion has a first cross dimension in a direction parallel to the electrical coupling interface that is smaller than a second cross dimension of the pore in said direction.

3. A resistive memory cell according to claim 1, comprising an annular spacer arranged in the pore and wherein the storage element is formed in the spacer.

4. A resistive memory cell according to claim 1, wherein the selector comprises a diode arranged in the pore.

5. A resistive memory cell according to claim 1, wherein the selector comprises a transistor and the coupling terminal is a conduction terminal of the transistor.

6. A resistive memory cell according to claim 5, wherein the selector comprises a bipolar transistor and the coupling terminal includes an emitter terminal of the transistor.

7. A resistive memory cell according to claim 6, wherein the selector comprises a base region, also accommodated in the pore.

8. A resistive memory cell according to claim 5, wherein the selector comprises a MOS transistor and the coupling terminal includes a drain terminal of the transistor.

9. A resistive memory cell according to claim 6, wherein the selector comprises a channel region, also accommodated in the pore.

10. A resistive memory cell according to claim 1, wherein the storage element is directly in contact with the electrical coupling interface of the coupling terminal.

11. A resistive memory cell according to claim 1, wherein the tubular portion has a thickness in the range of 5 nm to 20 nm.

12. A resistive memory cell according to claim 1, wherein the resistive memory material is a phase-change material.

13. A device, comprising:
a resistive memory that includes a plurality of resistive memory cells formed in a structural layer, each resistive memory cell including:
a pore in the structural layer;
a selector having a coupling terminal positioned in the pore, the coupling terminal including an electrical coupling interface; and
a storage element of a resistive memory material, the storage element being arranged in the pore, being electrically coupled to the coupling terminal of the selector, and including a tubular portion extending transversely to the electrical coupling interface of the coupling terminal.

14. A device according to claim 13, comprising a control unit coupled to the resistive memory.

15. A device according to claim 13, comprising a communication interface coupled to the resistive memory.

16. A device according to claim 13, wherein the tubular portion has a first cross dimension in a direction parallel to the electrical coupling interface that is smaller than a second cross dimension of the pore in said direction.

17. A device according to claim 13, comprising an annular spacer arranged in the pore and wherein the storage element is formed in the spacer.

18. A device according to claim 13, wherein the storage element is directly in contact with the electrical coupling interface of the coupling terminal.

19. A process for manufacturing a resistive memory cell, comprising:
forming a structural layer;
forming a pore in the structural layer;
forming a selector having a coupling terminal positioned in the pore, the coupling terminal including an electrical coupling interface;
forming a storage element of a resistive memory material in the pore, the storage element being electrically coupled to the coupling terminal, of the selector, forming the storage element including forming a tubular portion of the storage element that extends transversely to the electrical coupling interface of the coupling terminal.

20. A process according to claim 19, wherein forming the storage element comprises conformally depositing a resistive memory material in the pore.

21. A process according to claim 20, wherein depositing the resistive memory material comprises performing a Chemical Vapor Deposition.

22. A process according to claim 21, wherein Chemical Vapor Deposition includes MOCVD.

23. A process according to claim 20, comprising reducing a cross dimension of the pore before forming the storage element.

24. A process according to claim 23, wherein reducing the cross dimension of the pore comprises forming an annular spacer in the pore.

25. A process according to claim 19, wherein forming the selector comprises epitaxially growing the coupling terminal selectively within the pore.

26. A process according claim 19, wherein forming the selector comprises, before forming the pore, forming a conductive region by implanting ions in a substrate of the wafer and defining the coupling terminal by selectively etching the conductive region.

27. A process according to claim 26, wherein forming the pore comprises forming the structural layer around the coupling terminal.

28. A process according to claim 19, wherein the resistive memory material is a phase-change material.
